(19) United States
(12) Patent Application Publication
(10) Pub. No.: US 2025/0343067 A1
(43) Pub. Date: Nov. 6, 2025

(54) VOLUME REDUCTION IN SEMICONDUCTOR PROCESSING CHAMBER

(71) Applicant: Applied Materials, Inc., Santa Clara, CA (US)

(72) Inventors: Muhannad MUSTAFA, Milpitas, CA (US); Yixiong YANG, San Jose, CA (US); Yongjing LIN, San Jose, CA (US); Srinivas GANDIKOTA, Santa Clara, CA (US); Rakesh RAMADAS, Santa Clara, CA (US); Aditya CHUTTAR, Santa Clara, CA (US); Jing ZHENG, Santa Clara, CA (US)

(21) Appl. No.: 18/652,311

(22) Filed: May 1, 2024

(51) Int. Cl. H01L 21/687

(52) U.S. Cl. CPC H01L 21/68785; H01L 21/68742

(57) ABSTRACT

A processing system for semiconductor manufacturing includes a chamber housing and a substrate support disposed in the chamber housing. The system also includes a lift pin coupled to the substrate support and a ring for actuating the lift pin. The ring is movable between a raised position and a lowered position. An expandable filler is disposed in the chamber housing. The expandable filler has an expanded configuration when the ring is in the raised position and has a contracted configuration when the ring is in the lowered position.

### BACKGROUND

### Field

Embodiments of the present invention generally relate to components, apparatus, and systems for semiconductor manufacturing. More specifically, the present technology relates to a processing chamber having a component that reduces the processing volume of the processing chamber.

### Description of the Related Art

Integrated circuits are made possible by processes which produce intricately patterned material layers on substrate surfaces. Producing patterned material on a substrate requires controlled methods for forming and removing material. Gases and precursors are often delivered to a processing region and distributed to uniformly deposit or etch material on the substrate.

Some methods involve sequentially delivering different precursors to the processing region. For example, the precursors may be pulsed alternately, one at a time, into the processing region. Inert gas is supplied between the precursors to purge the processing region to prevent gas phase reactions. The process of alternately supplying and purging precursors is timing consuming, thereby limiting throughput. The process also increases production costs due to the purging of unused precursors.

There is, therefore, a need for improved systems and methods that can increase throughput and reduce the amount of precursors used.

### SUMMARY

Embodiments herein include a processing system for semiconductor manufacturing. In one embodiment, a processing system for semiconductor manufacturing includes a chamber housing and a substrate support disposed in the chamber housing. The system also includes a lift pin coupled to the substrate support and a ring for actuating the lift pin. The ring is movable between a raised position and a lowered position. An expandable filler is disposed in the chamber housing. The expandable filler has an expanded configuration when the ring is in the raised position and has a contracted configuration when the ring is in the lowered position. In some examples, the expandable filler comprises one or more bellows.

In another embodiment, a processing system for semiconductor manufacturing includes a chamber body and a chamber lid disposed on top of the chamber body. A showerhead is coupled to the chamber lid, and a substrate support is disposed in the chamber body and below the showerhead. The system also includes a lift pin coupled to the substrate support and a ring for actuating the lift pin. The ring is movable between a raised position and a lowered position. The system further includes an expandable filler and a static filler block disposed in the chamber housing. The expandable filler has an expanded configuration when the ring is in the raised position and has a contracted configuration when the ring is in the lowered position; and

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 illustrates a schematic view of a multi-chamber processing system, according to one or more embodiments described herein.

FIG. 2 is a schematic illustration of a deposition chamber in which a substrate support is raised, according to one or more embodiments described herein.

FIG. 3 is a schematic illustration of the deposition chamber of FIG. 2, in which the substrate support is lowered.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In one embodiment, a processing system for semiconductor manufacturing includes a chamber housing and a substrate support disposed in the chamber housing. The system also includes a lift pin coupled to the substrate support and a ring for actuating the lift pin. The ring is movable between a raised position and a lowered position. An expandable filler, a static filler block, or both are disposed in the chamber housing and occupy a portion of the chamber volume. The expandable filler has an expanded configuration when the ring is in the raised position and has a contracted configuration when the ring is in the lowered position. The static filler block occupies a fixed amount of the chamber volume. In this respect, the expandable filler and the static filler block beneficially reduce the volume inside the chamber housing. The reduced chamber volume advantageously allows for faster pressure cycling during substrate processing, such as during chemical deposition. Additionally, the reduced chamber volume provides more efficient purging of the precursors from the chamber before the next precursor is supplied.

### Exemplary Processing System

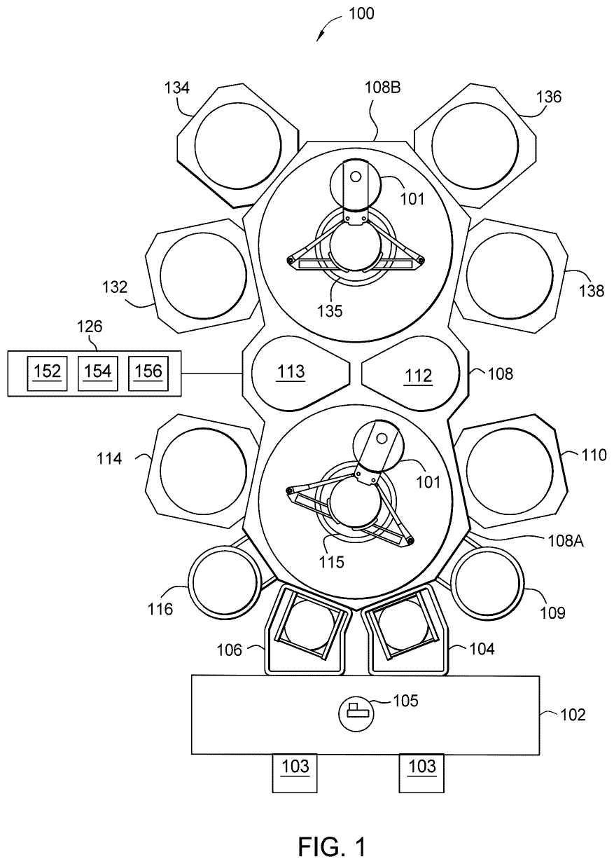

FIG. 1 is a schematic top view of a substrate processing system, according to certain embodiments. The substrate processing system 100 generally includes an equipment front-end module (EFEM) 102 for loading substrates into the substrate processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from front opening unified pods (FOUPs) 103 to at least one of the first load lock chamber 104 or a second load lock chamber 106 coupled to the EFEM 102. Proceeding counterclockwise around a buffer portion 108A of the transfer chamber 108 from the first load lock chamber 104, the substrate processing system 100 includes a first degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates 101 to each of the load lock chambers 104, 106, the degas chambers 109, 116, the pre-clean chambers 110, 114 and the pass-through chambers 112, 113.

A back-end portion 108B of the transfer chamber 108 includes a second robot 135 that is configured to transfer substrates 101 to each of the pass-through chambers 112, 113 and processing chambers coupled to the back-end portion 108B of the substrate processing system 100. The processing chambers can include a first processing chamber 132, a second processing chamber 134, a third processing chamber 136, and a fourth processing chamber 138. In general, the processing chambers 132, 134, 136, 138 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138 are an ALD chamber that is configured similar to the processing chamber 200 described below.

The buffer portion 108A and back-end portion 108B of the transfer chamber 108 and each chamber coupled to the transfer chamber 108 are maintained at a vacuum state. As used herein, the term “vacuum” may refer to pressures less than 760 Torr, and will typically be maintained at pressures near 10.5 Torr (i.e., ˜10-3 Pa). However, some high-vacuum systems may operate below near 10-7 Torr (i.e., ˜10-5 Pa). In certain embodiments, the vacuum is created using a rough pump and/or a turbomolecular pump coupled to the transfer chamber 108 and to each of the one or more process chambers (e.g., process chambers 109-138). However, other types of vacuum pumps are also contemplated.

A system controller 126, such as a programmable computer, is coupled to the substrate processing system 100 for controlling one or more of the components therein. For example, the system controller 126 may control the operation of the processing chamber 200, which is described further below. In operation, the system controller 126 enables data acquisition and feedback from the respective components to coordinate processing in the substrate processing system 100. The system controller 126 includes a programmable central processing unit (CPU) 152, which is operable with a memory 154 (e.g., non-volatile memory) and support circuits 156. The support circuits 156 (e.g., cache, clock circuits, input/output subsystems, power supplies, etc., and combinations thereof) are conventionally coupled to the CPU 152 and coupled to the various components within the substrate processing system 100.

In some embodiments, the CPU 152 is one of any form of general purpose computer processor used in an industrial setting, such as a programmable logic controller (PLC), for controlling various monitoring system component and sub-processors. The memory 154, coupled to the CPU 152, is non-transitory and is typically one or more of readily available memory such as random access memory (RAM), read only memory (ROM), floppy disk drive, hard disk, or any other form of digital storage, local or remote.

Herein, the memory 154 is in the form of a computer-readable storage media containing instructions (e.g., non-volatile memory), that when executed by the CPU 152, facilitates the operation of the substrate processing system 100. The instructions in the memory 154 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

### Exemplary Processing Chamber

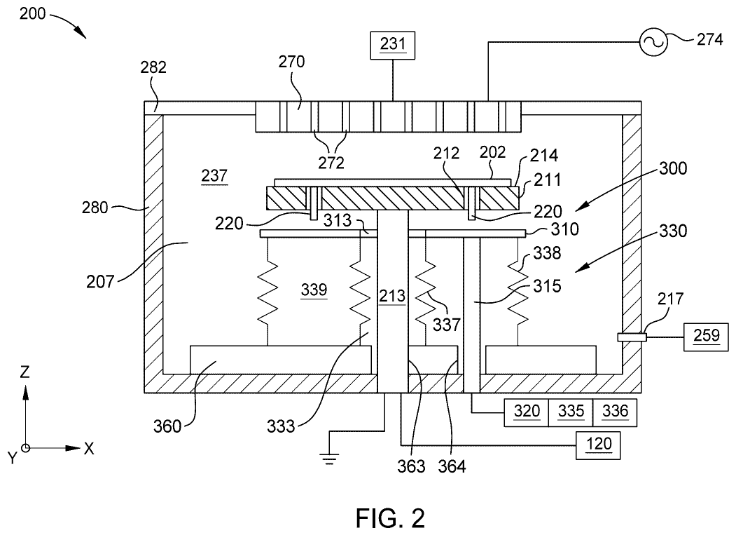

FIG. 2 is a schematic illustration of a processing chamber 200 according to embodiments of the present disclosure. The processing chamber 200 can be any one of the chambers the processing chambers 132, 134, 136, 138 within FIG. 1. The processing chamber 200 is an atomic layer deposition (ALD) chamber and may be used as the first chamber within the substrate processing system 100. The processing chamber 200 is utilized to grow a silicide on a substrate, such as the substrate 202.

The processing chamber 200 includes a chamber body 280, a chamber lid 282, a showerhead 270, a substrate support 211, and an exhaust outlet 217. The chamber body 280, the chamber lid 282, and the showerhead 270 define a processing volume 237. The chamber body 280 and the chamber lid 282 exemplify a chamber housing. The processing volume 237 forms an upper portion of the chamber volume 207 of the chamber body 280. The chamber volume 207 also includes the space around and below the substrate support 211 that is in fluid communication with the processing volume 237. The chamber lid 282 is disposed on top of the chamber body 280 with the showerhead 270 either disposed underneath or within the chamber lid 282.

The showerhead 270 may alternatively be a plate stack and is not limited to the showerhead 270 design disclosed herein. The showerhead 270 includes one or more apertures 272 through which a gas is flown into the processing volume 237. The gas may be flown from a gas delivery system 231 into the processing volume 237. The gas delivered to the showerhead 270, the processing volume 237, or both, from the gas delivery system 231 may be an inert gas, a process gas, a purge gas, a precursor, or any combination thereof. The gas delivery system 231 controls the quantity, pressure, temperature, concentration, and flow rate of the gas into the showerhead 270, the processing volume 237, or both. The gas delivery system 231, in some embodiments, may include multiple gas resources. For example the gas delivery system 231 may be a precursor delivery system configured to deliver one or more precursors to the showerhead 270, the processing volume 237, or both.

The showerhead 270 is connected to a radio frequency (RF) power source 274. The RF power source 274 is configured to provide a bias between the substrate support 211 and the showerhead 270. Alternatively, the RF power source 274 may be connected to the substrate support 211 and the showerhead 270 may be grounded.

The exhaust outlet 217 is connected to both the processing volume 237 and an exhaust pump 259. The exhaust outlet 217 and the exhaust pump 259 remove gases from the processing volume 237. The exhaust outlet 217 is disposed through the chamber body 280.

The substrate support 211 is disposed within the processing volume 237 and is configured to support a substrate 202. The substrate support 211 includes a planar upper surface 214 sized to receive the substrate 202. The substrate support 211 is connected to a shaft 213. The shaft 213 extends from the bottom side of the substrate support 211 and is configured to be raised, lowered, or rotated. In some embodiments, the shaft 213 and the substrate support 211 are connected to one or more motors or actuators 120. The shaft 213 and the substrate support 211 are grounded. FIG. 2 shows the substrate support 211 in a raised position, in which the substrate 202 is in position for processing, such as undergoing atomic layer deposition. In some embodiments, the substrate support 211 includes a heating feature for controlling the temperature of the substrate 202.

A plurality of lift pins 220 are disposed in thru-holes 212 in the substrate support 211. The lift pins 220 can be raised or lowered to correspondingly lift or lower the substrate 202 relative to the upper surface 214 of the substrate support 211. As shown in FIG. 2, the lift pins 220 are in a lowered position, in which the top of the lift pins 220 are at or below the top surface of the substrate support 211. In this position, the substrate 202 is disposed on the upper surface 214 of the substrate support 211 and is in position for processing.

The chamber 200 includes a lift pin actuator 300, according to some embodiments. The lift pin actuator 300 includes a ring 310 coupled to a ring drive shaft 315. A drive motor 320 is configured to move the ring drive shaft 315, thereby raising or lowering the ring 310. The ring 310 is disposed below the lift pins 220 and is engageable with the bottom of the lift pins 220 when the substrate support 211 is lowered. In one embodiment, the ring 310 is shaped like a flat disk, which has a central opening 313 to accommodate the shaft 213 of the substrate support 211.

The chamber 200 also includes an expandable filler 330 for occupying a portion of the chamber volume 207. An exemplary expandable filler 330 is one or more bellows 337, 338. In some embodiments, a first bellows 337 and a second bellows 338 are disposed between the ring 310 and the bottom of the chamber 200. The bellows 337, 338 have an annular shape and arranged concentrically relative to each other. The first bellows 337 has a central opening 333 and is disposed inside of the second bellows 338. The shaft 213 of the substrate support 211 extends through the central opening 333 of the first bellows 337. In one embodiment, the ring 310 is disposed on the upper surface of the bellows 337, 338. In another embodiment, the ring 310 is integral with the bellows 337, 338 and forms the top surface of the bellows 337, 338. The bottom of the bellows 337, 338 is disposed on the bottom of the chamber body 280. The inner, first bellows 337 is coupled to the inner diameter of the ring 310, but may be smaller or larger than the inner diameter of the ring 310. The outer, second bellows 338 is coupled to the outer diameter of the ring 310, but may be smaller or larger than the outer diameter of the ring 310. In some examples, the outer bellows 338 is larger (e.g., wider) than the outer diameter of the ring 310. A bellows volume 339 is defined by the ring 310, the inner bellows 337, the outer bellows 338, and the bottom of the bellows 337, 338. The bellows volume 339 can be pressurized or evacuated, as will be discussed below.

As seen FIG. 2, the ring drive shaft 315 is at least partially disposed inside the bellows volume 339. The ring drive shaft 315 is configured to raise or lower the ring 310 and the top surface of the bellows 337, 338. In this respect, the bellows 337, 338 are expanded when the ring 310 is raised, and the bellows 337, 338 are contracted when the ring 310 is lowered.

The bellows 337, 338 are connected to a bellows fluid source 336 and a pump 335 to supply or remove the bellows fluid from the bellows volume 339. For example, the pump 335 can deliver bellows fluid from the bellows fluid source 336 to the bellows volume 339 during expansion of the bellows 337, 338. The pump 335 can remove the bellows fluid from the bellows volume 339 as the bellows 337, 338 are contracted. The bellows fluid may be air, inert gas, or other suitable gas for use with the bellows 337, 338. In some embodiments, during substrate processing, the pressure in the bellows 337, 338 is maintained at the same or higher pressure than the pressure in the chamber volume 207. It is contemplated the bellows 337, 338 or other expandable filler 330 can have any suitable shape for selectively occupying a portion of the chamber volume 207. In some embodiments, the bellows 337, 338 are sized to occupy from 20% to 85% of the chamber volume 207 between the contracted configuration and the expanded configuration. In some embodiments, the bellows 337, 338 are sized to occupy from 30% to 80% of the chamber volume 207 between the contracted configuration and the expanded configuration.

In some embodiments, the chamber 200 includes a static filler block 360 for occupying a portion of the chamber volume 207 of the chamber 200. In the example shown in FIG. 2, the static filler block 360 has an annular shape with a central opening 363. The size of the static filler block 360 remains the same during substrate processing. The shaft 213 of the substrate support 211 extends through the central opening 363 of the static filler block 360. The bottom of the static filler block 360 is disposed on the bottom of the chamber body 280. The static filler block 360 also includes an opening 364 for accommodating the ring drive shaft 315. The top surface of the static filler block 360 is below the ring 310. In this embodiment, the bellows 330 is disposed on top of the static filler block 360. Although an annular shape is described, the static filler block 360 may have any suitable size for occupying a portion of the chamber volume 207. In some embodiments, the static filler block 360 is made of a polymeric material, a metallic material such as aluminum alloy, nickel, or stainless steel, or any combination thereof.

In some embodiments, the static filler block 360 is sized to occupy from 10% to 50% or from 15% to 45% of the chamber volume 207. In some embodiments, the combination of the static filler block 360 and the bellows 337, 338 may occupy from 30% to 85% of the chamber volume 207 or from 40% to 80% of the chamber volume 207. However, it is contemplated the chamber 200 can include the static filler block 360 without the bellows 337, 338 or other expandable filler. By occupying a portion of the chamber volume 207, the expandable filler, such as the bellows 337, 338, and the static filler block 360 beneficially reduce the size of the chamber volume 207 during substrate processing. The reduced chamber volume 207 advantageously allows for faster pressure cycling during substrate processing, such as chemical deposition. Additionally, the reduced chamber volume 207 provides more efficient purging of the precursors from the chamber 200 before the next precursor is supplied.

In some embodiments, the expandable filler and the static filler block 360 are removably installed in the chamber 200. For example, the static filler block 360 can be removed to change its size to occupy more or less volume in the chamber 200. In another example, the static filler block 360 can be installed as a retrofit in an existing processing chamber.

In some embodiments, the chamber 200 includes two or more expandable fillers. In one example, the chamber 200 includes a first pair of bellows 337, 338 stacked on top of a second pair of bellows 337, 338. During substrate processing one or both pair of bellows can be expanded or retracted. For example, the upper pair of bellows can be expanded while the lower pair of bellows remains static in size.

In operation, the substrate support 211 raises the substrate 202 toward the showerhead 270 for processing, such as undergoing chemical deposition, as shown in FIG. 2. In this position, the substrate support 211 and the substrate 202 are in an upper, processing position. The ring 310 is also in a raised position. In turn, the bellows 337, 338 are in an expanded configuration. The bellows 337, 338 are disposed on the static filler block 360. The volume occupied by the static filler block 360 is fixed. The expanded bellows 337, 338 and static filler block 360 reduce the chamber volume 207 of the chamber 200 in an amount from 30% to 85% of the chamber volume 207.

During processing, a plurality of precursors are pulsed alternately, one at a time, into the processing volume 237. Inert gas is supplied between the precursors to purge the processing volume 237 to prevent gas phase reactions of the precursors. The reduced chamber volume 207 allows for more efficient purging of the precursors before the next precursor is supplied. Additionally, the reduced chamber volume 207 allows for faster pressure cycling of the chamber volume 207. As a result of the reduced chamber volume 207, throughput of the processing system is increased.

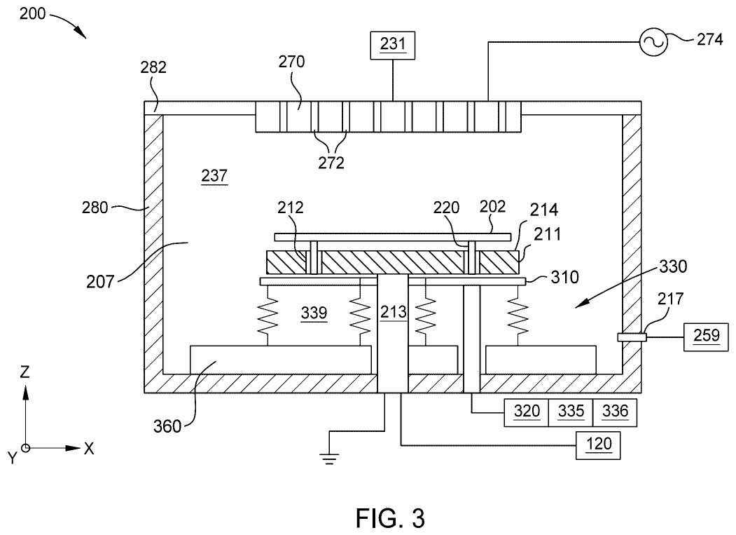

After processing, the substrate 202 is lowered by lowering the substrate support 211, as shown in FIG. 3. As the substrate support 211 moves down, the bottom of the lift pins 220 contacts the ring 310. As the substrate support 211 continues to move down, the lift pins 220 project through the thru-holes 212, and the substrate support 211 is lowered relative to the substrate 202 being held by the lift pins 220. While the substrate support 211 is lowered, the ring 310 is also lowered by the ring drive shaft 315, which causes the bellows 337, 338 to contract. During contraction, bellows fluid is evacuated from the bellows volume 339. In the contracted configuration, the bellows 337, 338 occupy a smaller portion of the chamber volume 207. In this respect, the bellows 337, 338 can be selectively expanded to occupy more of the chamber volume 207 when the substrate support 211 is raised during substrate processing.

Benefits of the present disclosure include reduced gas consumption and gas waste, increased process time, and increased throughput.

While the foregoing is directed to embodiments of the present disclosure, other and further embodiments of the disclosure may be devised without departing from the basic scope thereof, and the scope thereof is determined by the claims that follow

What is claimed is:

1. A processing system for semiconductor manufacturing, the processing system comprising:
a chamber housing;
a substrate support disposed in the chamber housing;
a lift pin coupled to the substrate support;
a ring for actuating the lift pin, the ring movable between a raised position and a lowered position; and
an expandable filler disposed in the chamber housing, the expandable filler having an expanded configuration when the ring is in the raised position and having a contracted configuration when the ring is in the lowered position.

2. The processing system of claim 1, wherein the expandable filler is disposed below the ring.

3. The processing system of claim 1, further comprising a ring drive shaft for moving the ring between the raised position and the lowered position.

4. The processing system of claim 3, wherein the ring drive shaft is at least partially disposed inside the expandable filler.

5. The processing system of claim 1, wherein the expandable filler has an annular shape with a central opening.

6. The processing system of claim 1, further comprising a static filler block disposed inside the chamber housing and below the ring.

7. The processing system of claim 6, wherein the expandable filler is disposed on the static filler block.

8. The processing system of claim 1, wherein expandable filler occupies from 30% to 85% of a chamber volume of the chamber housing.

9. The processing system of claim 1, wherein the expandable filler comprises a first bellows disposed inside a second bellows.

10. The processing system of claim 9, further comprising a fluid source for supplying a bellows fluid into a bellow volume of the first and second bellows.

11. The processing system of claim 1, wherein the ring is integral with the expandable filler.

12. A processing system for semiconductor manufacturing, the processing system comprising:
a chamber body;
a chamber lid disposed on top of the chamber body;
a showerhead coupled to the chamber lid;
a substrate support disposed in the chamber body and below the showerhead;
a lift pin coupled to the substrate support;
a ring for actuating the lift pin, the ring movable between a raised position and a lowered position;
an expandable filler disposed in the chamber housing, the expandable filler having an expanded configuration when the ring is in the raised position and having a contracted configuration when the ring is in the lowered position; and
a static filler block disposed in the chamber housing.

13. The processing system of claim 12, wherein the expandable filler is disposed below the ring.

14. The processing system of claim 12, further comprising a ring drive shaft for moving the ring between the raised position and the lowered position.

15. The processing system of claim 14, wherein the ring drive shaft is at least partially disposed inside the expandable filler.

16. The processing system of claim 12, wherein the expandable filler has an annular shape with a central opening.

17. The processing system of claim 12, wherein the expandable filler is disposed on the static filler block.

18. The processing system of claim 12, wherein the expandable filler occupies from 30% to 85% of a chamber volume of the chamber housing.

19. The processing system of claim 12, wherein the expandable filler comprises a pair of bellows.

20. The processing system of claim 11, wherein the ring is integral with the expandable filler.
